(19) United States
(12) Patent Application Publication
(10) Pub. No.: US 2025/0341593 A1
(43) Pub. Date: Nov. 6, 2025

(54) MAGNETIC FIELD SENSING DEVICE

(71) Applicant: MAGCAM, Leuven (BE)

(72) Inventor: Koen VERVAEKE, Linden (BE)

(73) Assignee: MAGCAM, Leuven (BE)

(21) Appl. No.: 18/866,476

(22) PCT Filed: May 16, 2023
(86) PCT No.: PCT/EP2023/063119

§ 371 Date: Nov. 15, 2024

(30) Foreign Application Priority Data
May 19, 2022 (BE) 2022/5385

(51) Int. Cl. G01R 33/00; G01R 33/032; G01R 33/10; G01R 33/26

(52) U.S. Cl. CPC G01R 33/0094; G01R 33/0023; G01R 33/032; G01R 33/10; G01R 33/26

(57) ABSTRACT

Magnetic field sensing device A magnetic field sensing device and a method are described for measuring magnetic field distributions, comprising a predetermined area of a diamond NV center substrate and a controller. The predetermined area has a plurality of magnetic sensing elements which can be selectively activated and read-out. To enable a magnetic sensing element to sense a magnetic field simultaneously a local electrical field is generated, the sensing element is exposed to light of a predetermined wavelength or wavelength range, the magnetic element is irradiated with microwaves of a predetermined frequency or frequency range, and the photocurrent generated is collected and measured allowing to extract sensed magnetic field values therefrom.

### CROSS-REFERENCE TO RELATED APPLICATION

This application claims priority to, and the benefit of, Belgium Application No. 2022/5385 (“Magnetic field sensing device”), filed on May 19, 2022, the entire contents of which are incorporated herein by reference.

### FIELD OF THE INVENTION

The invention relates to the field of devices and methods for sensing magnetic field distributions.

### BACKGROUND

Devices for measuring the magnetic field distributions of any permanent magnet and magnet assemblies are known in the art. Such devices are referred to as magnetic field sensing devices, sometimes also referred to as magnetic field cameras, and are composed of multiple magnetic field sensing elements to allow localized measurements enabling e.g. to determine the spatial distribution of the magnetic field in the area sensed by the magnetic field sensing device with appropriate resolution. These magnetic field sensing elements may be arranged in 1-dimensional or 2-dimensial arrays in the form of a matrix or grid.

An example of such magnetic field sensing device is disclosed in EP1720026A1. The magnetic field sensing elements used are Hall sensors arranged in the form of a matrix. To enable individually addressing each of the Hall sensors in the matrix switches are used in the form of transistors. Hall sensors and switches are made of a semiconductive material.

In recent years approaches for measuring magnetic fields using diamond Nitrogen Vacancy (NV) center materials have been studied. For examples Bourgeois, E., Jarmola, A., Siyushev, P. et al. Photoelectric detection of electron spin resonance of nitrogen-vacancy centres in diamond. Nat Commun 6, 8577 (2015) describes two such approaches: Optical Detection of Magnetic Resonance (ODMR) and Photocurrent Detection of Magnetic Resonance (PDMR).

Existing magnetic field sensing devices composed of Hall sensors and transistor switches made of a semiconductive material have their merits for measuring magnetic field distributions.

U.S. Pat. No. 10,901,054B1 discloses an integrated optical waveguide and electronic using quantum defect centers. Like many current designs, the pair of electrodes therein are arranged opposite to each other in a more or less symmetrical manner. However, such arrangement results in generating a non uniform electrical field, in particular at the ends. Therefore, the magnetic fields of adjacent sensing devices may interfere with each other and result in inaccurate results.

It is however an aim of the present invention to provide an alternative magnetic field sensing device and method to make the measuring result more accurate.

It is a further aim of the present invention to integrate such magnetic field sensing device on a diamond NV center substrate to obtain a higher spatial resolution of the magnetic field sensing element and to improve measurement sensitivity and overall measurement time.

### SUMMARY OF THE INVENTION

To achieve these aims in an aspect of the present invention a magnetic field sensing device for determining the magnetic field distribution in an area has been provided, comprising a predetermined area of a diamond NV center substrate and a controller. The predetermined area has a plurality of magnetic sensing elements, each of said plurality of sensing elements has a first contact and a second contact electrically contacting a surface of the diamond NV center substrate. Each second contact is electrically isolated from each first contact.

The diamond NV center substrate may constitute a diamond material containing Nitrogen Vacancy (NV) centers in the form of a thin plate.

In accordance with the invention, the controller is configured to control
a biasing element to apply a bias voltage to the first contacts of a selection of the plurality of sensing elements, thereby generating a local external electrical field in each of the selected sensing elements, while the selected sensing elements are illuminated by at least one light source, thereby inducing a photocurrent in each of the selected sensing elements, and irradiated by at least one microwave source, thereby influencing the photocurrent generated in each of the selected sensing elements;
a measurement unit to measure the photocurrent detected by each of the second contacts of the selected sensing elements, and extract sensed magnetic field values therefrom for each sensing element of the selected sensing elements,
adjustment of the selection of the plurality of sensing elements allowing obtaining sensed magnetic field values for each selectable sensing element of the predetermined area. It is to be understood that the number of sensing elements in the predetermined area determines the maximum resolution. So, in case a measurement is performed at the maximum resolution, all of the selectable sensing elements are controlled as described and magnetic field values are extracted for each sensing element in the predetermined area. It can however be decided to measure at lower resolution and hence use only part of the available sensing elements in the predetermined area to perform a measurement over the complete predetermined area, or in other words only part of the sensing elements in the predetermined area is selectable. Alternatively, at lower resolution all sensing elements are used for the measurement but sensed magnetic field values are only extracted for combinations of sensing elements in accordance with the desired resolution.

The measurement unit typically comprises an amplifier, equipment for measuring a current and/or voltage, signal processing means and a data processing unit.

To enable a magnetic sensing element to sense a magnetic field simultaneously a local electrical field is to be generated by applying a bias voltage between the first and second contact of the sensing element, the sensing element must be exposed to light of a predetermined wavelength or wavelength range, and the magnetic element is to be irradiated with microwaves of a predetermined frequency or frequency range. The combined presence of the local electrical field and the exposure to light induces and enables collection of a photocurrent. Simultaneously irradiating with microwaves influences the photocurrent dependent on the presence of a magnetic field. Hence by electrically connecting the second contact of the sensing element to a measurement unit sensed magnetic field values can be extracted by the measurement unit from the photocurrent detected by the second contact. The above can be repeated for each sensing element in order to sequentially obtain the magnetic field contributions of each individual sensing element or can be done in parallel for selected magnetic sensing elements by connecting the second contact of each selected magnetic sensing element separately to a measurement unit. The capability to extract sensed magnetic field values for each individual magnetic sensing element, so called read-out selectivity, can be achieved in several ways without the need to connect each second contact separately. Non-selected magnetic sensing elements that have no local external field applied and/or are not exposed to light do not generate a photocurrent. Hence if their second conductive line is connected to the second contact of a selected magnetic sensing element read-out selectivity of the selected magnetic sensing element is not affected. Spatially controlling the light sources and the electrical fields creates design-freedom allowing for less complex design and faster and more accurate measurements. When grouping second contacts read-out selectivity can also be accomplished by modulating the bias voltage and/or the light source and/or the microwave source such as to expose different magnetic sensing elements or groups thereof to signals with different modulation frequencies allowing to separate the contribution of individuals magnetic sensing elements to the photocurrent detected by the grouped second contacts using a multifrequency lock-in amplifier.

In an embodiment of the invention either one of the first and second contact of the magnetic sensing element is located inward to the other one of the first and second contact. In particular, the arrangement may be such that one of the first and second contact of a magnetic sensing element substantially surrounds the other one of the first and second contact, i.e the two contacts have different shapes, and one extends around the other (along a closed line or only partially). For example one contact is a spot (of any shape) located at the centre of the sensing element while the other contact is a line arranged towards the periphery of the sensing element. Doing so contributes in defining the substrate area (between the two contacts) to which an electrical field is applied as well as the uniformity of the electrical field in the magnetic sensing element. Moreover, it also improves shielding a magnetic sensing element from influencing by neighbouring magnetic sensing elements.

The plurality of sensing elements may be arranged in a 1D or 2D array such as to define a matrix or grid of magnetic sensing elements forming the magnetic sensing device. First parallel conductive lines oriented in a first direction may be provided to connect the first contacts and second parallel conductive lines oriented in a second direction may be provided to connect the second contacts. This allows to connect the first and second contacts of rows and/or columns of magnetic sensing elements in the matrix.

The first direction can be chosen perpendicular to the second direction. Hence the first conductive lines may connect the first contacts of rows of magnetic sensing elements while the second conductive lines may connect the second contacts of columns of magnetic sensing elements, or vice versa. This is convenient as the first and second conductive lines can easily be accessed at different sides of the magnetic sensing device. A multiplexer may be provided to which all the second conductive lines are connected while the output of the multiplexer is connected to the measurement unit. Thereby all the second contacts are connected and they can be read out by the measurement unit in rows or columns. For example, assume the first conductive lines connect rows of magnetic sensing elements and the second conductive lines, i.e. the read-out lines, connects columns of magnetic sensing elements and that a single row of magnetic sensing elements is selected and biased such that an electrical field is present in each sensing element of that row. When simultaneously this row of sensing elements is exposed to light at a predetermined wavelength and irradiated with microwaves at a predetermined frequency then in each sensing element of that row a photocurrent is generated influenced by the magnetic field to the extent present. In such case each column has only one active sensing element, or in other words each read-out line addresses a single active sensing element. Hence from the photocurrent measured by the measurement unit, as the read-out lines are selectively connected to the measurement unit by the multiplexer, the sensed magnetic field values of a single magnetic sensing cell can be extracted.

In an embodiment of the invention, when the biasing element is controlled to bias the first contacts of the selected sensing elements, the biasing element may be further controlled to connect the first contacts of the non-selected sensing elements to ground. As the second contacts are all grounded this suppresses potential noise picked up by the second contacts of non-selected sensing elements which could potentially affect the reliability and accuracy of the photocurrent measured and by consequence also the reliability and accuracy of sensed magnetic field values extracted.

Alternatively in case plural rows of sensing elements are selected (activated) at once the biasing element may be controlled to apply a differently modulated bias voltage to each of the associated first conductive lines. The measured photocurrent in a read-out lines then contains contributions of magnetic sensing elements of plural rows but each contribution is modulated differently and can be separately extracted using at least one lock-in amplifier, or equipment for analog to digital conversion and subsequent FFT analysis such as e.g. a spectrum analyzer.

The at least one microwave source may be one or more RF antennas. The at least one microwave source may be controlled while irradiating to sweep frequency within a predetermined frequency range. The at least one microwave source may be configured to irradiate the magnetic sensing elements directly. Alternatively, a set of parallel microwave conductive lines may be provided for carrying a microwave signal generated by the at least one microwave source, the microwave lines being formed above the first and/or second contacts, and being electrically insulated from the first and second contacts and from the substrate. The microwave conductive lines may be positioned such that they at least partially cover portions of the substrate that are not covered by the first and or second contacts. In particular the microwave conductive lines may be configured to maximize coverage of the substrate portions uncovered by the first and/or second contacts to thereby maximize coupling in of microwaves into the diamond material.

In an embodiment of the invention the microwave lines are alternatingly connected to ground such as to define a set of coplanar microwave strips or a set of coplanar waveguides. In another embodiment there are dedicated ground electrodes, e.g. each connecting some of the second contacts, provided in-between the microwave lines, so as to obtain a coplanar waveguide structure without the need to alternate the microwave lines with microwave ground lines.

In a further embodiment of the invention the set of parallel microwave conductive lines are oriented parallel to the second conductive lines. Referring back to the matrix example here above this would mean that the microwave lines are parallel to the read-out lines, or in other words the columns of magnetic sensing elements.

In yet a further embodiment the at least one microwave source may be controlled to generate a modulated microwave signal.

In another embodiment of the invention the first contacts and second contacts are formed on the same surface of the substrate and the light generated by the at least one light source is directed to an opposite surface such as to illuminate the selected sensing elements. This is advantageous as the light is then not shielded by the contacts hence increasing the exposed surface and/or volume of the substrate.

The illumination, independent of the surface where it is incident upon, may be continuous across the predetermined area. Alternatively, the illumination is spatially varied across the predetermined area. Spatial variation may be obtained by mechanically displacing the light source, or by using one or more reflective elements such as at least one mirror, e.g. a polygon mirror, or by using at least one diffractive element, or by using multiple light sources that can be selectively addressed. In particular, the at least one light source may be a focused laser beam, or a line-shaped laser beam, or a 1-dimensional or two-dimensional array of LEDs or lasers such as e.g. Vertical Cavity Surface emitting lasers (VCSELs).

In a further embodiment of the present invention the measurement unit is configured to extract from the measured photocurrent sensed temperature values for each sensing element of the selected sensing elements.

In another aspect of the invention a method is provided for determining the magnetic field distribution in an area using a magnetic field sensing device comprising a predetermined area of a diamond NV center substrate, the predetermined area having a plurality of sensing elements, each of said plurality of sensing elements having a first contact and a second contact electrically contacting a surface of the diamond NV center substrate, said second contact being electrically isolated from said first contact; the method comprising the steps of:
applying a bias voltage to the first contacts of a selection of the plurality of sensing elements, thereby generating a local external electrical field in each of the selected sensing elements, while illuminating the selected sensing elements by at least one light source, thereby inducing a photocurrent in each of the selected sensing elements, and irradiating the selected sensing elements by at least one microwave source, thereby influencing the photocurrent generated in each of the selected sensing elements;
measuring the photocurrent detected by each of the second contacts of the selected sensing elements, and extracting sensed magnetic field values therefrom for each sensing element of the selected sensing elements, and
adjusting the selection of sensing elements and repeating the steps of the method till sensed magnetic field values are obtained for each selectable sensing element of the predetermined area.

The method also comprises placing the object for which the magnetic field distribution has to be determined in the proximity of the sensing elements, preferably at a defined distance of the sensing elements. Then the sensed magnetic field values are used to compute the magnetic field distribution, as known in the art.

Said object to be measured can be of any type and in any technical field. For example, the method of the invention can be used for bio-detection or biosensing within samples of various shapes, size or containers. The high sensitivity reached thanks to the method of the invention can for example allow to determine the magnetic field distribution within microfluidic devices, on chips or wafers, to monitor functioning of electronic systems, like detecting small currents on an integrated circuit. It can also be used for static measurements for quality control in a production context for example.

### BRIEF DESCRIPTION OF DRAWINGS

FIG. 1 shows a schematic top view of an example of a magnetic field sensing device according to the invention.

FIG. 2 shows a schematic perspective view of an example of an array of magnetic field sensing elements according to the invention.

FIG. 3 shows the backside of the schematic perspective view of the array of magnetic field sensing elements of FIG. 2 according to an embodiment of the invention.

The figures are made for illustrative purposes and members may not have correct proportions to each other.

### DETAILED DESCRIPTION OF EMBODIMENTS OF THE INVENTION

List of reference numbers used:
1: Diamond NV center substrate
2: First contact, biasing contact
3: Second contact, read-out contact
4: First conductive lines, biasing lines
5: Second conductive lines, read-out lines
6: Biasing element
7: Read-out line selection unit, multiplexer
8: Transimpedance amplifier, current amplifier
9: Lock-in amplifier/Frequency analyzer/ADC
10: Microwave line
11: Microwave Ground line
12: Controller
13: Microwave source
14: Microwave line selection unit
15: Sensing area
16: Data processing unit
17: Backside of Diamond NV center substrate
18: Backside ground electrode

Examples of the invention will now be described in more detail with reference to the drawings.

It will be understood that, although the terms “first,” “second,” etc., may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section, without departing from the spirit and scope of the inventive concept.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the inventive concept refers to “one or more embodiments of the present invention.”

It will be understood that when an element is referred to as being “connected to” or “coupled to” another element, it can be directly connected to or coupled to the other element, or one or more intervening elements may be present. When an element is referred to as being “directly connected to,” or “directly coupled to,” another element, there are no intervening elements present.

As used herein, the terms “substantially,” “about,” and similar terms are used as terms of approximation and not as terms of degree, and are intended to account for the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

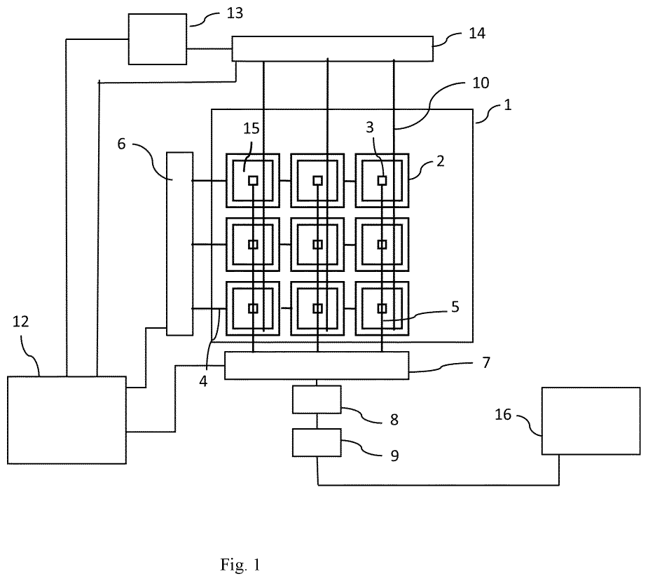

FIG. 1 illustrates a magnetic field sensing device comprising a predetermined area of a diamond NV center substrate (1) shown in the x-y plane, the predetermined area having a plurality of sensing elements, each of said plurality of sensing elements having a first contact (2) and a second contact (3) electrically contacting a surface of the diamond NV center substrate (1), said second contact (3) being electrically isolated from said first contact (2).

The diamond NV center substrate (1) is a diamond material containing Nitrogen Vacancy (NV) centers in the form of a thin plate having a surface area (in the x-y plane) typically in the range from 4 mm by 4 mm till 10 mm by 10 mm, and a thickness typically in the range from 100 μm to 500 μm.

The second or read-out contact (3) of each of the magnetic sensing elements is located inward to its first or bias contact (2). In operation a bias voltage will be applied between the bias contact (2) and the read-out contact (3) of a sensing element and thereby create an electrical field in the substrate volume (15) of that sensing element. Hence adequately positioning and defining the contacts contributes to maximizing the sensing area (15) as well as the uniformity of the electrical field in the sensing area of the magnetic sensing element.

The plurality of sensing elements of the magnetic sensing device as exemplified in FIG. 1 are arranged in a 2D array such as to define a 3 by 3 matrix or grid of magnetic sensing elements forming the magnetic sensing device. Although a 3 by 3 matrix is used as example, other configurations may be chosen dependent on the shape and geometry of the area to be sensed such as e.g. a matrix of sensing elements selected from a range of dimensions comprising 1×2, 2×2, 5×5, 5×10, 1×10, 5×1, 10×10, 100×100, 1000×1000.

Parallel conductive biasing lines (4) horizontally oriented connect the bias contacts (2) of rows of magnetic sensing elements. Parallel conductive read-out lines (5) vertically oriented connect the read-out contacts (3) of columns of magnetic sensing elements.

The width of the contacts and the conductive lines is typically in the range from 1 μm to 10 μm, while the thickness may typically range from 0.1 μm to 1 μm. The closest distance between a bias contact and a read-out contact of a same magnetic sensing element is typically in the range from 5 μm to 100 μm. The distance or pitch between read-out contact of adjacent magnetic sensing elements is an indication for the maximum resolution and is typically in the range from 10 μm to 200 μm.

A set of parallel microwave conductive lines (10) is provided for carrying a microwave signal. The microwave lines are formed using known techniques as used in semiconductor processing and manufacturing of integrated circuits and MEMS devices. The microwave lines are positioned above (in the z direction) the bias and read-out contacts (2) (3) and the bias and read-out lines (4) (5), and are electrically insulated therefrom and from the substrate. The microwave conductive lines are positioned such that they at least partially cover portions of the substrate that are not covered by the bias and read-out contacts. In particular the microwave conductive lines may be configured to maximize coverage of the substrate portions uncovered by the bias and read-out contacts to thereby maximize coupling in of microwaves into the diamond material. The set of parallel microwave conductive lines (10) is oriented parallel to the read-out lines (5), or in other words the columns of magnetic sensing elements.

To enable a magnetic sensing element to sense a magnetic field simultaneously a local electrical field is to be generated, the sensing element must be exposed to light of a predetermined wavelength or wavelength range, the magnetic element is to be irradiated with microwaves of a predetermined frequency or frequency range, and the photocurrent generated is to be collected and measured allowing to extract sensed magnetic field values therefrom. This can be enabled as follows:
1. The diamond substrate is illuminated with light of the appropriate wavelength (typically green, but also blue light and even combinations of different colors such as green and red, or green and yellow can be used), in order to excite charge carriers to the conduction band and to the excited NV states.
2. Microwave electromagnetic radiation in the vicinity of 2.87 GHz is applied to the NV centers in order to resonantly excite charge carriers from the ground (³A₂) 0 state to the degenerate (³A₂)+/−1 NV states. This allows more charge carriers to fall back from the excited (3E)+/−1 NV states to the ground NV states through the two metastable ¹A₁ and ¹E NV states, thereby generating an associated change in electrical photocurrent as charge carriers decaying through these metastable NV states, do not contribute to the photocurrent. A fixed frequency may be chosen. This can be done when the resonance frequencies are known, e.g. determined in a previous calibration step. The microwave radiation may also be applied while sweeping the microwave frequency over a predetermined range around 2.87 GHz, e.g. from 2.80 GHz to 2.94 GHz or from 2.70 GHz to 3.04 GHz with steps of e.g. 1 MHz.
3. The generated photocurrent is collected by applying for example a bias voltage in the range from 1V to 50V between bias contact and read-out contact on the diamond surface. This bias voltage creates an electric field in the diamond having a magnitude in the range from 102 V/cm to 105 V/cm between said bias and read-out contact that collects the generated charge carriers in the conduction band towards one of the contacts. The collected photocurrent is further measured at the fixed frequency or at each frequency within the predetermined frequency range. When the photocurrent is collected and measured as the frequency of the microwave field is swept over a range in the vicinity of 2.87 GHz, reductions in the photocurrent at certain resonance frequencies are observed. These absorption minima occur in pairs, centered around a common center frequency. The location of this center frequency is typically 2.87 GHz, but can shift with temperature. The distance between each pair of minima, expressed in units of microwave frequency, is proportional to the magnetic field along one of the crystallographic axes. Thus measuring the distance between the minima gives information about the sensed magnetic field allowing to extract sensed magnetic field values from the photocurrent measured. Moreover, the common center frequency of all minima pairs is temperature dependent and hence the local temperature at the measurement location can thus be extracted from the photocurrent spectrum.

The sensor described in the present invention can thus also be used as a temperature sensor array, or as a combined magnetic field and temperature sensor array.

As illustrated in FIG. 1 a controller (12) is connected to a biasing element (6), a read-out line selection unit (7) of a measurement unit, a microwave source (13) and a microwave line selection unit (14). The biasing element (6) is connected to each row of bias contacts (2) via the associated bias line (4). The microwave source (generator) (13) is connected to the microwave lines (10) via the microwave line selection unit. The read-out lines (5) are connected to the read-out line selection unit (7). In an operational mode, the controller (12) is configured to control
the biasing element (6) to apply a bias voltage to the bias contacts (2) of a selection of the nine sensing elements, while the selected sensing elements are illuminated with light and irradiated with microwaves,
a measurement unit to measure the photocurrent detected by each of the read-out contacts (3) of the selected sensing elements, and extract sensed magnetic field values therefrom for each sensing element of the selected sensing elements,
adjustment of the selection of sensing elements and repeating the foregoing control steps till sensed magnetic field values are obtained for each selectable sensing element, i.e. all nine sensing elements when measuring at maximum resolution.

The read-out procedure for the matrix of magnetic sensing elements can be as follows:

Apply a bias voltage to a selected one of the biasing lines. At the same time the other biasing lines may be connected to ground.

Illuminate at least the sensing areas (15) of the selected magnetic sensing elements (in this example the sensing elements of the selected row or in other words the sensing elements associated with the selected biasing line (4)) with light of the appropriate wavelength or wavelength band.

Generate microwave signals with the microwave source (13) while sweeping the microwave frequency over a range around 2.87 GHz, e.g. from 2.80 GHz to 2.94 GHz or from 2.70 GHz to 3.04 GHz with steps of e.g. 1 MHz and carry the generated signals to at least the sensing areas (15) of the selected sensing elements using the microwave lines (10) such that the microwaves can be coupled into the substrate at these sensing areas (15).

For every microwave frequency, measure the photocurrent detected via the read-out lines (5). The read-out lines may be read-out selectively by a measurement unit using a multiplexer (7). Alternatively this can be done simultaneously using parallel current measurement equipment. The photocurrent in each read-out line comprises substantially solely the photocurrent detected by the read-out contact of the selected sensing element. The other sensing elements of the read-out line are not active. As moreover their bias contacts are connected to ground potential impact of noise picked up by the read-out contacts of these other non-active sensing elements is suppressed. The measurement unit comprises a transimpedance amplifier (8) and a data processing unit (16). The transimpedance amplifier converts the electric photocurrent to an electric voltage. Alternatively, instead of a transimpedance amplifier (8) a (low noise) current amplifier may be used. The resulting signal may then be processed further by the measurement unit using signal processing means such as e.g. a lock-in amplifier, an analog-to-digital converter, a spectrum analyzer and/or other electric measurement and/or analysis equipment (9). The measurement result obtained is hence associated with an individual selected sensing element, or in other words is associated with a single sensing area (15). From that measurement result the data processing unit (16) extracts the magnetic field values sensed by that single magnetic sensing element.

When results are obtained for each sensing element in the selected row, subsequently a bias voltage can be applied to another bias line (4) and the procedure as described here above can be repeated till all bias lines have been selected.

As an alternative for the above read-out procedure, a bias voltage may be applied simultaneously to multiple selected bias lines (4), thereby amplitude modulating said bias voltage with different modulation frequencies for different selected bias lines. The photocurrent detected by a read-out line comprises contributions from multiple selected sensing elements. The transimpedance amplifier (8) converts the electric photocurrent to an electric voltage. The resulting signal of a read-out line is further analyzed using a multitude of lock-in amplifiers (9), or a spectrum analyzer, and/or subjected to Fourier analysis such as to determine the contribution at each of the different modulation frequencies, which each correspond to a single different bias line. A set of spectra is thus obtained, from each of which the local magnetic field can be extracted for an single sensing element. Instead of modulating the bias voltage such that each row of sensing elements is subjected to a signal having a different modulation frequency, one may opt to modulate the illumination signal with different modulation frequencies for different rows, or in case the microwave lines are parallel to the biasing lines one may opt to modulate the microwave signal with different modulation frequencies for different microwave lines (rows).

Modulation may be applied to signal sources simultaneously, one of which being applied to the rows and the other one to the columns of sensing elements. For example, in the configuration as depicted in FIG. 1, one may opt to modulate the bias voltage with different frequencies for different bias lines (associated with rows) and the microwave signal with different frequencies for different microwave lines (columns). By doing so each sensing element can be subjected to a different and unique combination of bias voltage modulation and microwave modulation frequencies. In this case read-out lines of the selection of sensing areas can be connected together and be measured as a single photocurrent signal. The frequency spectrum of said single photocurrent signal then contains frequency components corresponding to combinations of all bias voltage and microwave modulation frequencies. As these combinations are chosen unique, the magnetic field at each individual sensing area can be measured by extracting its corresponding combined frequency from said photocurrent spectrum.

For example, the modulation frequencies, fb, of the bias voltage can be selected in the range between 1 kHz and 5 kHz and the modulation frequencies, fm, of the microwave lines can be selected in the range between 10 kHz and 100 kHz. The combined frequencies will then lie in the range between 11 kHz and 105 kHz, whereby the series lower lying frequencies is repeated around each of the higher frequencies, thus forming a multitude of frequency components corresponding to each combination of biasing voltage and microwave frequencies. These frequencies can furthermore be extracted from the photocurrent signal as described above using a multitude of lock-in amplifiers, or a spectrum analyzer, or a Fourier analysis.

When selecting modulation frequencies care is taken that no combined frequencies occur at the same position in the spectrum, since some folded back frequencies around a certain frequency could coincide with some frequencies around a lower lying modulation frequency. Therefore, the distance between subsequent higher frequencies e.g. fm1 and fm2 should be at least twice the value as the range of lower lying frequencies fb1 to fbn.

The multitude of unique combined frequencies that are simultaneously present in the measured photocurrent signal can be further separated using spectral techniques such as lock-in amplification, spectrum analysis, FFT analysis.

As previously discussed, in order to extract magnetic field values from the measured photocurrents, the photocurrent is measured at a multitude of microwave frequencies, whereby absorption minima (peaks) are observed at certain frequencies. These minima occur in pairs, centered around a common center frequency. The distance between each pair of minima, expressed in units of microwave frequency, is proportional to the magnetic field along one of the crystallographic axes of the diamond lattice of the diamond NV center substrate. Each NV center is oriented along one of the four crystallographic axes of the diamond lattice, and is only sensitive to the local magnetic field component along that crystallographic direction. Since the multitude of NV centers of the diamond NV substrate are randomly distributed among the four crystallographic orientations, each of these orientations will have a more or less equal sensitivity.

A magnetic field that is oriented such that it has components along each of the four lattice orientations, will thus cause four pairs of resonance peaks (minima) in the photocurrent spectrum, since each of the orientations senses a non-zero magnetic field along its direction.

To resolve the magnetic field components along the different crystallographic orientations, a bias magnetic field may be applied to offset each minima pair so they are separated and can be individually detected. The bias magnetic field can be applied to the sensing device using one or more permanent magnets, or one or more electromagnets, such as e.g. Helmholz coils.

Since space is 3-dimensional, it is sufficient to measure along three of the four crystallographic orientations in order to fully decompose the applied magnetic field into its Cartesian components. To only see three pairs of resonance peaks (minima) in the photocurrent spectrum, the applied bias magnetic field may be oriented such that it is perpendicular to one of the four crystallographic orientations. That direction will then not be sensitive to the magnetic field and only three pairs of resonance peaks will appear in the spectrum, together with the single peak of the fourth direction (which is not split since there is no magnetic field along that direction). The spectrum will thus consist of 7 peaks, only 6 of which are used to determine the magnetic field components along the three sensitive crystallographic orientations.

A conversion can then be performed to convert the measured field components along the crystallographic orientations to the Cartesian coordinate system. This can be performed if the magnetic sensing device was first calibrated by applying magnetic fields along each of the Cartesian dimensions and recording the response of each pair of resonance peaks. This procedure results in a transformation formula to convert between crystallographic orientations components and Cartesian components. This allows to apply during actual measurements a (constant) bias magnetic field perpendicular to one of the crystallographic orientations (thereby only exciting three crystallographic orientations) and record any deviations therefrom.

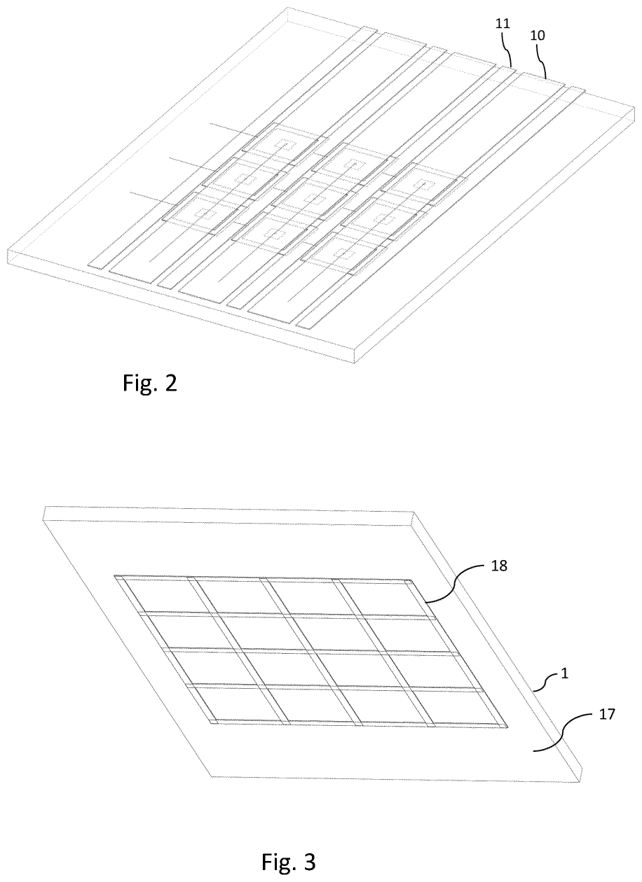

In FIG. 1 a set of microwave lines (10) is provided for carrying each a microwave signal to corresponding sensing areas (15). Alternatively, as shown in the perspective view of FIG. 2 for a same 3 by 3 matrix of sensing elements as in FIG. 1, a set of parallel microwave conductive lines (10) for carrying a microwave signal and a set of microwave ground lines (11) are provided in an alternating coplanar configuration such as to form in each column of the matrix of sensing elements a coplanar waveguide. The microwave lines (10) of the coplanar waveguides are positioned above (in the z direction) the bias and read-out contacts (2) (3) and the bias and read-out lines (4) (5), and are electrically insulated therefrom and from the substrate. The microwave conductive lines are positioned such that they cover the sensing areas (15). The set of parallel microwave conductive lines (10) is oriented parallel to the read-out lines (5), or in other words the columns of the magnetic sensing elements. The microwave ground lines (11) are positioned coplanar between the microwave lines (10) such that each microwave line (10) is flanked by a microwave ground line (11) at each side in its length direction. The microwave ground lines (11) are electrically insulated from the substrate, the bias and read-out contacts (2) (3) and the microwave lines (10). In an operative condition of the magnetic sensing device, the microwave ground lines (11) are connected to ground. This coplanar waveguide topology allows to maintain a constant impedance of e.g. 50 Ohm along the full trajectory of the microwave line (10) such that the microwave energy is effectively transmitted over the diamond surface.

As illustrated in FIG. 3 an additional backside ground electrode (18) may be provided at the backside (17) of the diamond NV center substrate, i.e. the side of the substrate opposite to the side carrying the microwave lines, to optimize substrate exposure to microwave irradiation. The backside ground electrode is preferably designed such that there remains sufficient uncovered substrate surface at the backside (17) of the diamond NV center substrate to allow illumination of the substrate from the backside (17).

Advantageously, the sensing device of the invention is incorporated into the adequate hardware to allow its use for measuring the magnetic field distribution of specific objects.

The method also comprises placing the object for which the magnetic field distribution has to be determined in the proximity of the sensing elements, preferably at a defined distance of the sensing elements. Then the sensed magnetic field values are used to compute the magnetic field distribution, as known in the art.

Said object to be measured can be of any type and in any technical field. For example, in medical imaging and diagnostics, the sensor array could be used for magnetoencephalography (MEG), a non-invasive technique that measures the magnetic fields produced by neuronal activity in the brain. MEG signals are typically in the range of a few femtoteslas to hundreds of femtoteslas. The high sensitivity and spatial resolution of the sensor array would improve the detection of brain activity and potentially lead to better diagnosis and treatment of neurological disorders. The array could also contribute to the development of high-resolution magnetic resonance imaging (MRI) systems, improving diagnostic capabilities. MRI systems typically use magnetic fields ranging from 0.5 T to 3 T or higher.

In nanotechnology and material science, the sensor array could be employed in magnetic force microscopy (MFM), a technique used to map the magnetic properties of materials at the nanoscale. The high spatial resolution and sensitivity would enable detailed mapping of magnetic domains in materials, contributing to the understanding of magnetic properties and the development of new materials. Additionally, the array could be used to characterize magnetic nanoparticles, which are commonly in the size range of 10-100 nm and have magnetic fields in the range of milliteslas (mT) at close proximity. Magnetic nanoparticles have applications in drug delivery, hyperthermia cancer treatment, and magnetic separation.

In biological and chemical sensing, the sensor array could be utilized to detect and quantify the presence of magnetically labelled biomolecules, such as proteins or DNA, in biological samples. The high sensitivity reached thanks to the method of the invention can for example allow to determine the magnetic field distribution within microfluidic devices. This could lead to the development of highly sensitive diagnostic tools and assays. The array could also enable the study of magnetic field changes due to chemical reactions, providing insights into reaction mechanisms and kinetics.

Lastly, in electronics and data storage, the high spatial resolution and sensitivity of the sensor array could be used to read and write magnetic data storage devices, such as magnetic random-access memory (MRAM), with increased data density and performance. MRAM devices typically use magnetic fields in the range of 1 picotesla to 1 microtesla, depending on the measurement distance which could typically range from 1 micrometer to 100 micrometer. The sensor array could also be used to detect and locate defects in magnetic devices or materials, enabling improved quality control and failure analysis.

The invention can be furthermore used to monitor the functioning of electronic systems, like detecting small currents on integrated circuits or printed circuit boards. It can also be used for static measurements for quality control in a production context for example.

In summary, the high sensitivity, spatial resolution, and wide range of detectable magnetic fields of the magnetic sensor array open up numerous possibilities across various fields of research and industry, including medical imaging, nanotechnology, biological and chemical sensing, and electronics.

While this invention has been described in detail with particular references to illustrative embodiments thereof, the embodiments described herein are not intended to be exhaustive or to limit the scope of the invention to the exact forms disclosed. Persons skilled in the art and technology to which this invention pertains will appreciate that alterations and changes in the described structures and methods of assembly and operation can be practiced without meaningfully departing from the principles, spirit, and scope of this invention, as set forth in the following claims and equivalents thereof.

1. A magnetic field sensing device for determining the magnetic field distribution in an area comprising:
a predetermined area of a diamond NV center substrate, the predetermined area having a plurality of sensing elements, each of said plurality of sensing elements having a first contact and a second contact electrically contacting a surface of the diamond NV center substrate, said second contact being electrically isolated from said first contact; wherein in each sensing element, one of the first and second contact is located inward to the other one of the first and second contact, and
a controller;
wherein, in an operational mode, the controller is configured to control
a biasing element to apply a bias voltage to the first contacts of a selection of the plurality of sensing elements, thereby generating a local external electrical field in each of the selected sensing elements, while the selected sensing elements are illuminated by at least one light source, thereby inducing a photocurrent in each of the selected sensing elements, and irradiated by at least one microwave source, thereby influencing the photocurrent generated in each of the selected sensing elements;
a measurement unit to measure the photocurrent detected by each of the second contacts of the selected sensing elements, and extract sensed magnetic field values therefrom for each sensing element of the selected sensing elements, and
adjustment of the selection of the plurality of sensing elements allowing obtaining sensed magnetic field values for each selectable sensing element of the predetermined area.

2. The magnetic field sensing device as claimed in claim 1, wherein in each sensing element one of the first and second contact substantially surrounds the other one of the first and second contact.

3. The magnetic field sensing device as claimed in claim 1, wherein the plurality of sensing elements is arranged in a 1D or 2D array and wherein first parallel conductive lines oriented in a first direction connect the first contacts and second parallel conductive lines oriented in a second direction connect the second contacts.

4. The magnetic field sensing device as claimed in claim 3, wherein the first direction is perpendicular to the second direction.

5. The magnetic field sensing device as claimed in claim 3, wherein the measurement unit is connected to the second conductive lines via a multiplexer.

6. The magnetic field sensing device as claimed in claim 1, wherein the biasing element is controlled to connect the first contacts of the non-selected sensing elements to ground.

7. The magnetic field sensing device as claimed in claim 3, wherein the biasing element is controlled to apply a differently modulated bias voltage to each of the first conductive lines.

8. The magnetic field sensing device as claimed in claim 7, wherein the measurement unit comprises at least one lock-in amplifier.

9. The magnetic field sensing device as claimed in claim 1, further comprising a set of parallel microwave conductive lines for carrying a microwave signal generated by the at least one microwave source, the microwave lines being formed above the first and/or second contacts, and being electrically insulated from the first and second contacts and from the substrate.

10. The magnetic field sensing device as claimed in claim 9, wherein the microwave lines are alternatingly connected to ground such as to define a set of coplanar microwave strips or a set of coplanar waveguides.

11. The magnetic field sensing device as claimed in claim 9, wherein the set of parallel microwave conductive lines are oriented parallel to the second conductive lines.

12. The magnetic field sensing device as claimed in claim 10, wherein the at least one microwave source is controlled to generate a modulated microwave signal.

13. The magnetic field sensing device as claimed in claim 1, wherein the at least one microwave source is controlled while irradiating to sweep frequency within a predetermined frequency range.

14. The magnetic field sensing device as claimed in claim 1, wherein the first contacts and second contacts are formed on the same surface of the substrate and the light generated by the at least one light source is directed to an opposite surface such as to illuminate the selected sensing elements.

15. The magnetic field sensing device as claimed in claim 1, wherein the illumination is continuous across the predetermined area.

16. The magnetic field sensing device as claimed in claim 14, wherein the illumination is spatially varied across the predetermined area.

17. The magnetic field sensing device as claimed in claim 16, wherein the at least one light source is a focused laser beam.

18. The magnetic field sensing device as claimed in claim 16, wherein the at least one light source is a line-shaped laser beam.

19. The magnetic field sensing device as claimed in claim 16, wherein the at least one light source is a 1-dimensional or two-dimensional array of LEDs or lasers.

20. The magnetic field sensing device as claimed in claim 1, wherein the measurement unit is configured to extract from the measured photocurrent sensed temperature values for each sensing element of the selected sensing elements.

21. A method for determining the magnetic field distribution in an area using a magnetic field sensing device comprising a predetermined area of a diamond NV center substrate, the predetermined area having a plurality of sensing elements, each of said plurality of sensing elements having a first contact and a second contact electrically contacting a surface of the diamond NV center substrate, said second contact being electrically isolated from said first contact; wherein in each sensing element one of the first and second contact is located inward to the other one of the first and second contact, the method comprising the steps of:
applying a bias voltage to the first contacts of a selection of the plurality of sensing elements, thereby generating a local external electrical field in each of the selected sensing elements, while illuminating the selected sensing elements by at least one light source, thereby inducing a photocurrent in each of the selected sensing elements, and irradiating the selected sensing elements by at least one microwave source, thereby influencing the photocurrent generated in each of the selected sensing elements;
measuring the photocurrent detected by each of the second contacts of the selected sensing elements, and extracting sensed magnetic field values therefrom for each sensing element of the selected sensing elements; and
adjusting the selection of sensing elements and repeating the steps of the method till sensed magnetic field values are obtained for each selectable sensing element of the predetermined area.
